(19) United States
(12) Patent Application Publication
(10) Pub. No.: US 2018/0286791 A1
(43) Pub. Date: Oct. 4, 2018

(54) ELECTRONIC COMPONENT MODULE AND METHOD FOR MANUFACTURING ELECTRONIC COMPONENT MODULE

(71) Applicant: AISIN SEIKI KABUSHIKI KAISHA, Kariya-shi (JP)

(72) Inventors: Minoru SHINOHARA, Tokyo-to (JP); Hiroya SEIKE, Beppu-shi (JP)

(73) Assignee: AISIN SEIKI KABUSHIKI KAISHA, Kariya-shi (JP)

(21) Appl. No.: 15/921,924

(22) Filed: Mar. 15, 2018

(30) Foreign Application Priority Data
Mar. 28, 2017 (JP) 2017-063519

(51) Int. Cl. H01L 23/495; H01L 23/12; H01L 23/31; H01L 21/48

(52) U.S. Cl. CPC H01L 23/49537; H01L 21/4853; H01L 23/3157; H01L 23/12

(57) ABSTRACT

An electronic component module includes: a first lead frame including a mounting portion on which a chip is mounted, a relay portion connected to an electrode portion of the chip by a lead wire, and a first lead portion connected to the relay portion; a second lead frame including a second lead portion connected to the first lead portion and having a thickness larger than that of the first lead frame; a first molded portion that covers the mounting portion and the relay portion in a state where the first lead portion protrudes; and a second molded portion that covers a connecting portion between the first lead portion and the second lead portion in a state where the first lead portion and the second lead portion protrude.

### CROSS REFERENCE TO RELATED APPLICATIONS

This application is based on and claims priority under 35 U.S.C. § 119 to Japanese Patent Application 2017-063519, filed on Mar. 28, 2017, the entire contents of which are incorporated herein by reference.

### TECHNICAL FIELD

This disclosure relates to an electronic component module in which a chip is encapsulated in a molded portion, and a method for manufacturing such an electronic component module.

### BACKGROUND DISCUSSION

In the related art, electronic components in which a chip is encapsulated in a molded portion have been used. Connectors and harnesses to which such electronic components are connected may be standardized in advance, and the pitches of the lead terminals of the electronic components are designed according to the standards. However, chips have been miniaturized from the viewpoint of low power consumption, and the lead frames on which the chips are mounted are narrower than the standards of the connectors and harnesses. For example, JP 2013-032942A (Reference 1) and JP 2001-319700A (Reference 2) disclose technologies that may be used for connecting such lead frames having different pitches.

In a manufacturing method of a rotation detecting device described in Reference 1, a lead frame and a terminal exposed from a case are bonded together, and the bonding portion between the lead frame and the terminal and the airtightness holding portion of the case are immersed in a molten resin and then cured. Therefore, the time of the resin molding process is shortened.

In a terminal and a method of bonding the terminal and a lead, which are described in Reference 2, in order to improve the effectiveness of the bonding state at the time of performing resistance welding between the terminal and the lead, a slit is provided in the terminal to form an energizing path.

However, according to the techniques described in References 1 and 2, since the molded portion and the terminal are individually designed, the step of bonding the lead frame to the terminal by laser or ultrasonic welding and the step of bonding the case and the cap are separately provided, resulting in an increase in manufacturing cost.

Thus, a need exists for an electronic component module which is not susceptible to the drawback mentioned above.

### SUMMARY

An electronic component module according to an aspect of this disclosure includes: a first lead frame including a mounting portion on which a chip is mounted, a relay portion connected to an electrode portion of the chip by a lead wire, and a first lead portion connected to the relay portion; a second lead frame including a second lead portion connected to the first lead portion and having a thickness larger than that of the first lead frame; a first molded portion that covers the mounting portion and the relay portion in a state where the first lead portion protrudes; and a second molded portion that covers a connecting portion between the first lead portion and the second lead portion in a state where the first lead portion and the second lead portion protrude.

A method for manufacturing an electronic component module according to another aspect of this disclosure includes: fixing a first lead frame including a mounting portion on which a chip is to be mounted, a relay portion to be connected to an electrode portion of the chip by a lead wire, and a first lead portion connected to the relay portion, and a second lead frame including a second lead portion to be connected to the first lead portion and having a thickness larger than that of the first lead frame; mounting the chip on the mounting portion; wire-bonding the electrode portion of the chip and the relay portion using the lead wire and wire-bonding the first lead portion and the second lead portion using the lead wire; forming a first molded portion that covers the mounting portion and the relay portion in a state where the first lead portion protrudes, and a second molded portion that covers a connecting portion between the first lead portion and the second lead portion in a state where the first lead portion and the second lead portion protrude; and cutting an unnecessary portion, which hinders a function of the chip from being exhibited, of the first lead frame and the second lead frame protruding from the first molded portion and the second molded portion.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a top view of a first lead frame and a second lead frame;

FIG. 2 is a side view of the first lead frame and the second lead frame;

FIG. 3 is an enlarged view of a connecting portion between the first lead portion and the second lead portion;

FIG. 4 is a top view of an electronic component module; and

FIG. 5 is an enlarged view of a connecting portion between a first lead portion and a second lead portion according to another embodiment.

### DETAILED DESCRIPTION

An electronic component module disclosed here is configured to be implemented at a low cost even in a case of having lead frames of different thicknesses. Hereinafter, an electronic component module 1 of the present embodiment will be described.

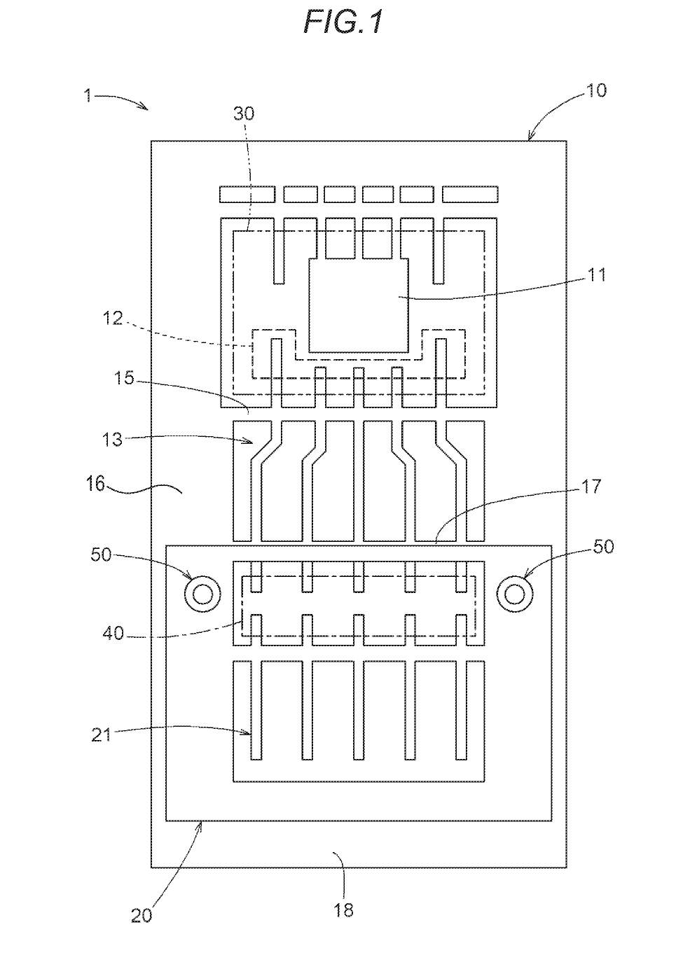

The electronic component module 1 includes a first lead frame 10, a second lead frame 20, a first molded portion 30, and a second molded portion 40. FIG. 1 illustrates a top view of the first lead frame 10 and the second lead frame 20 in a state where the second lead frame 20 is placed on the first lead frame 10.

The first lead frame 10 includes a mounting portion 11, a relay portion 12, and a first lead portion 13. The first lead frame 10 is made of a metal plate having a uniform thickness (e.g., oxygen-free copper having a thickness of 0.1 mm to 0.2 mm), and the mounting portion 11, the relay portion 12, and the first lead portion 13 are formed by pressing the metal plate.

A chip is mounted on the mounting portion 11. The chip corresponds to, for example, an electronic component (specifically, a Hall sensor, an acceleration sensor, a load sensor, a transistor, or the like) fabricated by individually dicing semiconductor devices formed on a semiconductor wafer. Of course, the chip is not limited to an active component such as a semiconductor device, but may be a passive component such as a resistor and a capacitor.

The relay portion 12 is connected to an electrode portion of the chip by a lead wire. The electrode portion of the chip may be a pair of positive and negative power electrodes that supply power to the chip, a signal electrode that inputs and outputs signals, or the like, depending on the type of the chip. The relay portion 12 is connected to the electrode portion of the chip by known wire bonding using the lead wire. Therefore, the relay portion 12 relays the chip and the first lead portion 13 (to be described later).

The first lead portion 13 is connected to the relay portion 12. In the present embodiment, as illustrated in FIG. 1, the first lead portion 13 is formed of the same lead frame as that of the relay portion 12. Therefore, the first lead portion 13 and the relay portion 12 are electrically connected, so that the electrode portion of the chip and the first lead portion 13 are electrically connected.

The second lead frame 20 is made of a metal plate having a uniform thickness larger than that of the first lead frame 10 (e.g., brass having a thickness of 0.65 mm), and a second lead portion 21 is formed by pressing the metal plate.

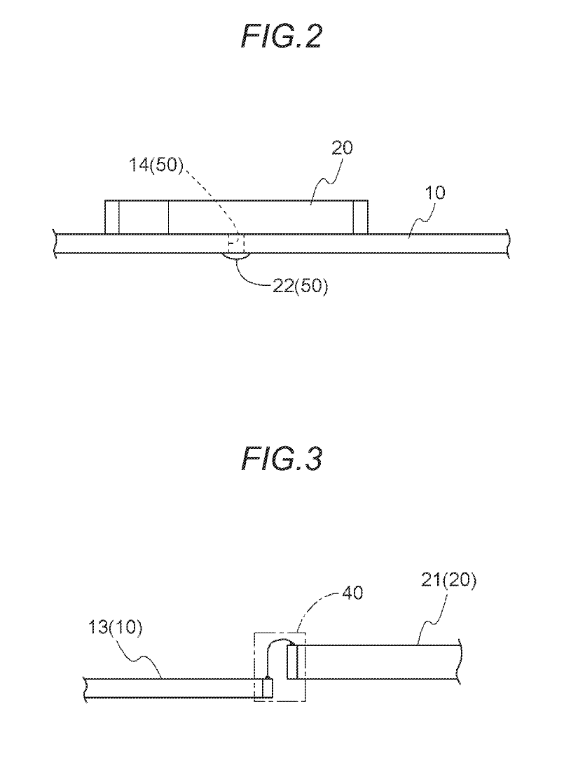

FIG. 2 illustrates a side view of the first lead frame 10 and the second lead frame 20 in a state where the second lead frame 20 is placed on the first lead frame 10. In the present embodiment, fixing portions 50 are provided across the first lead frame 10 and the second lead frame 20 in order to appropriately position and fix the first lead frame 10 and the second lead frame 20. The fixing portions 50 each includes a hole 14 provided at a predetermined position in the first lead frame 10 and a convex portion 22 provided at a position matching the hole 14 in the second lead frame 20. When the second lead frame 20 is placed on one surface of the first lead frame 10, the convex portion 22 is inserted through the hole 14, and when protruding to the other surface side of the first lead frame 10, the convex portion 22 is then pressed and crushed, thereby caulk-fixing the first lead frame 10 and the second lead frame 20. As illustrated in FIG. 1, in the present embodiment, two fixing portions 50 are provided, but three or more fixing portions 50 may be provided.

The second lead frame 20 includes a second lead portion 21. The second lead portion 21 is connected to the first lead portion 13. In the example of FIG. 1, the first lead portion 13 and the second lead portion 21 are spaced apart from each other, but as illustrated in FIG. 3 which is an enlarged cross-sectional view of the connecting portion between the first lead portion 13 and the second lead portion 21, the first lead portion 13 and the second lead portion 21 are connected by known wire bonding using a lead wire. Although each of the first lead portion 13 and the second lead portion 21 has plural leads, the leads of the first lead portion 13 and the leads of the second lead portion 21 are connected to each other by wire bonding. Therefore, the second lead portion 21 is electrically connected to the electrode portion of the chip via the relay portion 12 and the first lead portion 13. Further, since the connection is implemented by wire bonding, the height may be lowered. Therefore, the degree of freedom in arranging the electronic component module 1 may be increased.

The first molded portion 30 covers the mounting portion 11 and the relay portion 12 in a state where the first lead portion 13 protrudes. For ease of understanding, the first molded portion 30 is illustrated by a two-dot chain line in FIG. 1. The first molded portion 30 is formed by known resin molding so as to support the mold with a first tie bar 15 and a first outer peripheral portion 16 of the first lead frame 10 and encapsulate the mounting portion 11 and the relay portion 12. Therefore, the first lead portion 13 is in a state of protruding from the first molded portion 30.

The second mold portion 40 covers the connecting portion between the first lead portion 13 and the second lead portion 21 in a state where the first lead portion 13 and the second lead portion 21 protrude. In FIG. 1, the second molded portion 40 is illustrated by a single-dot chain line. The second molded portion 40 is formed by known resin molding so as to support the mold with a second tie bar 17 and a second outer peripheral portion 18 of the first lead frame 10 and encapsulate the portion connected by wire bonding, which corresponds to the connecting portion between the first lead portion 13 and the second lead portion 21. Therefore, the first lead portion 13 and the second lead portion 21 are in a state protruding from the second molded portion 40. In FIG. 1, the second tie bar 17 is disposed on the deep side of the paper surface of the second lead frame 20.

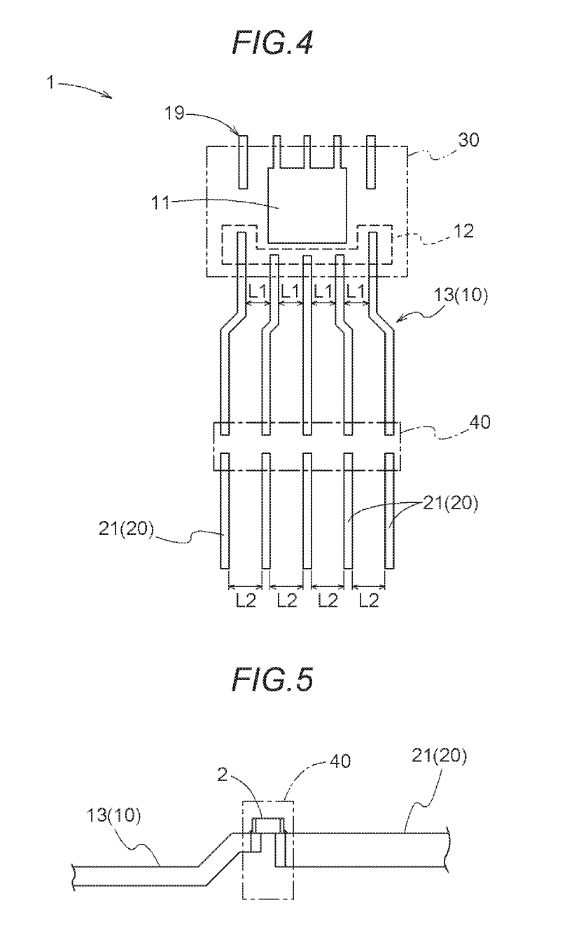

FIG. 4 illustrates a top view of the electronic component module 1. As illustrated in FIG. 4, the electronic component module 1 is in a state where unnecessary portions of the first lead frame 10 and the second lead frame 20 are cut. In the example of FIG. 4, a part of the first lead frame 10 protrudes from the surface of the first molded portion 30 that faces the surface from which the first lead portion 13 protrudes. The protrusion 19 protruding in this manner may be used, for example, as a test terminal of the electronic component module 1. Of course, the electronic component module 1 may be configured without providing the protrusion 19.

In the present embodiment, the interval between adjacent leads of the second lead portion 21 is wider than the interval between adjacent leads of a portion extending from the relay portion 12 among the plural leads of the first lead portion 13. The interval between adjacent leads of the second lead portion 21 is denoted by reference symbol L2 in FIG. 4. The interval between adjacent leads of the portion extending from the relay portion 12 among the plural leads of the first lead portion 13 is an interval of the portion protruding from the first molded portion 30 and is denoted by reference symbol L1 in FIG. 4. Therefore, in the present embodiment, the first lead portion 13 and the second lead portion 21 are formed so as to satisfy the relationship of L1<L2. As a result, even when the first lead frame 10 having a narrow pitch is used, the second lead portion 21 is formed at an interval corresponding to the terminals of the connector or the harness on which the electronic component module 1 is mounted, and the second lead portion 21 is used as an external connection terminal, thereby appropriately connecting the electronic component module 1 to the connector or the harness.

Next, a method of manufacturing the electronic component module 1 will be described. First, the first lead frame 10 including the mounting portion 11 on which a chip is to be mounted, the relay portion 12 to be connected to an electrode portion of the chip by a lead wire, and the first lead portion 13 connected to the relay portion 12 is fixed, and the second lead frame 20 including the second lead portion 21 to be connected to the first lead portion 13 and having a thickness larger than that of the first lead frame 10 is fixed. The fixation may be performed by caulk-fixing as described above. This step corresponds to a fixing step in the manufacturing method of the electronic component module 1.

Next, the chip is mounted on the mounting portion 11 of the first lead frame 10 to which the second lead frame 20 is fixed. This step corresponds to a mounting step in the manufacturing method of the electronic component module 1.

The electrode portion of the chip mounted on the mounting portion 11 and the relay portion 12 are wire-bonded using lead wires, and the first lead portion 13 and the second lead portion 21 are wire-bonded using lead wires. This step corresponds to a connecting step in the manufacturing method of the electronic component module 1.

After the connecting step is completed, the first molded portion 30 covering the mounting portion 11 and the relay portion 12 is formed in a state where the first lead portion 13 protrudes, and the second molded portion 40 covering the connection portion between the first lead portion 13 and the second lead portion 21 is formed in a state where the first molded portion 13 and the second lead portion 21 protrude. As described above, the first molded portion 30 may be formed by known resin molding so as to support the mold with the first tie bar 15 and the first outer peripheral portion 16 of the first lead frame 10 and encapsulate the mounting portion 11 and the relay portion 12, and the second molded portion 40 may be formed by known resin molding so as to support the mold with the second tie bar 17 and the second outer portion 18 of the first lead frame 10 and encapsulate the connecting portion between the first lead portion 13 and the lead portion 21. This step corresponds to a molding step in the manufacturing method of the electronic component module 1.

In the molding step, a cavity is used as a mold, but a cavity in a portion where the first lead frame 10 and the second lead frame 20 are overlapped may be configured to be divisionally movable, and elastically deformable pins may be provided on the back surface of the cavity so as to press the cavity from the back side. Thus, with the elastic deformation of the pins, it is possible to form two or more molded portions while ensuring the same surface pressure for the first lead frame 10 and the second lead frame 20 which are different in thickness from each other and suppressing resin leakage caused due to the thickness variation of the resin layers of the first lead frame 10 and the second lead frame 20.

After the first molded portion 30 and the second molded portion 40 are formed, unnecessary portions, which hinder a function of the chip from being exhibited, of the first lead frame 10 and the second lead frame 20 protruding from the first molded portion 30 and the second molded portion 40 are cut. The unnecessary portions which hinder the function of the chip from being exhibited are portions in which the chip is not able to perform a normal operation when the portions remain. In the present embodiment, the first tie bar 15, the second tie bar 17, and the outer peripheral portions of the first lead frame 10 and the second lead frame 20 described above correspond to the unnecessary portions. This step corresponds to a cutting step in the manufacturing method of the electronic component module 1. In this manner, the electronic component module 1 is constituted.

### Other Embodiments

In the above embodiment, it has been described that the first lead portion 13 and the second lead portion 21 are connected by wire bonding using lead wires. For example, as illustrated in FIG. 5, a portion of the first lead portion 13 connected to the second lead portion 21 may be brought closer to a portion of the second lead portion 21 connected to the first lead portion 13 in a side view of the first lead portion 13. Therefore, the tip end portion of the first lead portion 13 and the tip end portion of the second lead portion 21 can be made substantially flush with each other when the first lead portion 13 is viewed from the lateral side, so that, for example, the chip component 2 can be mounted over the first lead portion 13 and the second lead portion 21. Therefore, a circuit including a series component, which has not been able to be implemented by a lead frame in the related art, may be formed, for example, by mounting a resistor, a capacitor, a diode, and the like and then enclosing them with the second molded portion 40, and furthermore, it is unnecessary to take measures against abnormalities of the chip component 2. Such a configuration may be formed by pressing the tip end portion of the first lead portion 13 from the lower side. Alternatively, the configuration may be formed by placing a conductor (e.g., silver paste) on the tip end of the first lead portion 13 to make the tip end portion of the first lead portion 13 and the tip end portion of the second lead portion 21 substantially flush with each other.

In the above embodiment, it has been described that the interval of the second lead portion 21 is wider than the interval of the portion of the first lead portion 13 extending from the relay portion 12, but the interval of the second lead portion 21 may be equal to or narrower than the interval of the portion of the first lead portion 13 extending from the relay portion 12.

In the above embodiment, it has been described that the fixing portion 50 includes a hole 14 provided at a predetermined position in the first lead frame 10 and a convex portion 22 provided at a position matching the hole 14 in the second lead frame 20, but the fixing portion 50 may include a convex portion 22 provided at a predetermined position in the first lead frame 10 and a hole 14 provided at a position matching the convex portion 22 in the second lead frame 20. Even in this case, it is possible to caulk-fix the first lead frame 10 and the second lead frame 20.

This disclosure may be used for an electronic component module in which a chip is encapsulated in a molded portion, and a method for manufacturing such an electronic component module.

An electronic component module according to an aspect of this disclosure includes: a first lead frame including a mounting portion on which a chip is mounted, a relay portion connected to an electrode portion of the chip by a lead wire, and a first lead portion connected to the relay portion; a second lead frame including a second lead portion connected to the first lead portion and having a thickness larger than that of the first lead frame; a first molded portion that covers the mounting portion and the relay portion in a state where the first lead portion protrudes; and a second molded portion that covers a connecting portion between the first lead portion and the second lead portion in a state where the first lead portion and the second lead portion protrude.

According to this configuration, even in the case of using the first lead frame and the second lead frame having different thicknesses, it is possible to constitute the electronic component module in a single package. In addition, the connecting portion between the first lead frame and the second lead frame is covered and fixed by the second molded portion. Since the second molded portion can be formed by any known resin molding, it can be performed at low cost. In addition, even when the first lead frame is selected according to constraints on chip mounting and the second lead frame is selected according to constraints on the connector and the harness, it is possible to constitute the electronic component module in a single package. Therefore, it is possible to directly use the second lead frame, which is formed of a material different from the material of the first lead frame, as an external connection terminal. Furthermore, since a thin first lead frame is available, microfabrication is facilitated when patterning the first lead frame. Therefore, the degree of freedom of circuit formation can be improved.

It is preferable that each of the first lead portion and the second lead portion has a plurality of leads, and an interval between adjacent leads of the second lead portion is wider than an interval between adjacent leads of a portion extending from the relay portion among the plurality of leads of the first lead portion.

According to this configuration, it is possible to miniaturize the mounting portion and the relay portion connected to the first lead having narrow intervals between the leads. Therefore, it is possible to reduce the amount of the material used for forming the first molded portion. Further, since the first molded portion can be miniaturized, it is also possible to miniaturize the electronic component module.

It is preferable that a portion of the first lead portion connected to the second lead portion is brought close to a portion of the second lead portion connected to the first lead portion in a side view of the first lead portion.

According to this configuration, the first lead portion and the second lead portion can be electrically connected by mounting a chip component instead of wire bonding using a lead wire. As described above, according to this configuration, it is possible to achieve serial mounting, which is difficult to implement in a lead frame in the related art.

It is preferable that a tip end portion of the first lead portion and a tip end portion of the second lead portion are substantially flush with each other.

A method for manufacturing an electronic component module according to another aspect of this disclosure includes: fixing a first lead frame including a mounting portion on which a chip is to be mounted, a relay portion to be connected to an electrode portion of the chip by a lead wire, and a first lead portion connected to the relay portion, and a second lead frame including a second lead portion to be connected to the first lead portion and having a thickness larger than that of the first lead frame; mounting the chip on the mounting portion; wire-bonding the electrode portion of the chip and the relay portion using the lead wire and wire-bonding the first lead portion and the second lead portion using the lead wire; forming a first molded portion that covers the mounting portion and the relay portion in a state where the first lead portion protrudes, and a second molded portion that covers a connecting portion between the first lead portion and the second lead portion in a state where the first lead portion and the second lead portion protrude; and cutting an unnecessary portion, which hinders a function of the chip from being exhibited, of the first lead frame and the second lead frame protruding from the first molded portion and the second molded portion.

According to this configuration, it is possible to easily manufacture the electronic component module disclosed herein.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. An electronic component module comprising:
a first lead frame including a mounting portion on which a chip is mounted, a relay portion connected to an electrode portion of the chip by a lead wire, and a first lead portion connected to the relay portion;
a second lead frame including a second lead portion connected to the first lead portion and having a thickness larger than that of the first lead frame;
a first molded portion that covers the mounting portion and the relay portion in a state where the first lead portion protrudes; and
a second molded portion that covers a connecting portion between the first lead portion and the second lead portion in a state where the first lead portion and the second lead portion protrude.

2. The electronic component module according to claim 1,
wherein each of the first lead portion and the second lead portion has a plurality of leads, and
an interval between adjacent leads of the second lead portion is wider than an interval between adjacent leads of a portion extending from the relay portion among the plurality of leads of the first lead portion.

3. The electronic component module according to claim 1,
wherein a portion of the first lead portion connected to the second lead portion is brought close to a portion of the second lead portion connected to the first lead portion in a side view of the first lead portion.

4. The electronic component module according to claim 1,
wherein a tip end portion of the first lead portion and a tip end portion of the second lead portion are substantially flush with each other.

5. A method for manufacturing an electronic component module, comprising:
fixing a first lead frame including a mounting portion on which a chip is to be mounted, a relay portion to be connected to an electrode portion of the chip by a lead wire, and a first lead portion connected to the relay portion, and a second lead frame including a second lead portion to be connected to the first lead portion and having a thickness larger than that of the first lead frame;
mounting the chip on the mounting portion;
wire-bonding the electrode portion of the chip and the relay portion using the lead wire and wire-bonding the first lead portion and the second lead portion using the lead wire;
forming a first molded portion that covers the mounting portion and the relay portion in a state where the first lead portion protrudes, and a second molded portion that covers a connecting portion between the first lead portion and the second lead portion in a state where the first lead portion and the second lead portion protrude; and
cutting an unnecessary portion, which hinders a function of the chip from being exhibited, of the first lead frame and the second lead frame protruding from the first molded portion and the second molded portion.
